(19) United States
(12) Patent Application Publication
(10) Pub. No.: US 2008/0116554 A1
(43) Pub. Date: May 22, 2008

(54) PACKAGING MICRO DEVICES

(75) Inventor: Shaoher X. Pan, San Jose, CA (US)

Correspondence Address: FISH & RICHARDSON P.C., PO BOX 1022, MINNEAPOLIS, MN, 55440-1022, US

(73) Assignee: SPATIAL PHOTONICS, INC., Sunnyvale, CA (US)

(21) Appl. No.: 11/562,403

(22) Filed: Nov. 21, 2006

(51) Int. Cl. H01L 23/02; H01L 21/02

(52) U.S. Cl. 257/680; 438/127; 257/E21.002; 257/E23.194

(57) ABSTRACT

A method for applying anti-stiction material to a micro device includes encapsulating a micro device in a chamber, vaporizing anti-stiction material in a container to form vaporized anti-stiction material, transferring the vaporized anti-stiction material from the container to the chamber, and depositing the vaporized anti-stiction material on a surface of the micro device.

### BACKGROUND

The present disclosure relates to the packaging of micro devices.

Assuring reliability and yield are two critical tasks for the manufacturing of micro devices, such as integrated circuits and micro electro-mechanical systems (MEMS). Typically, in manufacturing micro devices, multiple micro devices are fabricated on a semiconductor wafer. The semiconductor wafer is then separated into individual dies each containing one or more individual micro devices. The electrical and optical performance of the micro devices are often tested for quality assurance on the individual dies in an ambient environment. For testing purposes, electrical and optical signals need to be properly input into the circuits in each micro device. Output electric and optical signals from the micro devices need to be properly detected and measured to analyze the functional performance of the micro devices. During testing and handling of the micro devices, the micro devices must not be contaminated by dust and pollutants in the ambient environment. Electrical and optical input and output, as well as protecting the micro devices from the environment, all need to be considered when designing packaging for the micro devices. A need therefore exists for improved packaging for micro devices to ensure desired and robust device performance.

### SUMMARY

In one general aspect, the present invention relates to a method for applying anti-stiction material to a micro device. The method includes encapsulating a micro device in a chamber, vaporizing anti-stiction material in a container to form vaporized anti-stiction material, transferring the vaporized anti-stiction material from the container to the chamber, and depositing the vaporized anti-stiction material on a surface of the micro device.

In another general aspect, the present invention relates to a micromechanical system that includes a chamber comprising an inlet to permit the transfer of a vaporized anti-stiction material into the chamber, a micro device encapsulated in the chamber, wherein the micro device comprises a first component and a second moveable component configured to contact the first component, and anti-stiction material coated on a surface of the first component or the second moveable component to prevent stiction between the first component and the second moveable component.

Implementations of the system may include one or more of the following. The method can further include evacuating the chamber before the step of transferring. The step of transferring can include diffusing the vaporized anti-stiction material into the chamber. The step of transferring can include connecting an outlet of the container with an inlet of the chamber to permit fluidic communication between the container and the chamber. The step of transferring can include opening a valve at the outlet of the container. The method can further include sealing the inlet of chamber after the step of transferring. The step of vaporizing can include heating the anti-stiction material. The step of vaporizing can include evaporating the anti-stiction material. The step of vaporizing can include subliming the anti-stiction material. The micro device can include a first component and a second moveable component configured to contact the first component. The method can further include depositing the vaporized anti-stiction material on a surface of the first component or a surface of the second moveable component to prevent stiction between the first component and the second moveable component. The second moveable component can be a micro mirror plate configured to tilt. The chamber can include a window transparent to at least one of visible, UV, or IR light. The anti-stiction material can include tridecafluoro-1,1,2,2,-tetrahydrooctyltrichlorosilane (FOTS) or heptadecafluoro-1,1,2,2,-tetrahydrooctyltrichlorosilane (FDTS).

Implementations may also include one or more of the following advantages. A potential advantage of the disclosed systems and methods is simplification of the fabrication process of the micro-device. Anti-stiction material can be applied to a plurality of micro devices after the micro devices are encapsulated in micro chambers on a semiconductor wafer (i.e., in situ). The anti-stiction material can be vaporized in a container. The vapor phase anti-stiction material can be transferred to a micro chamber containing a micro device through an inlet to the micro chamber. The evaporated anti-stiction material can be deposited on the surfaces of the micro devices to prevent stiction between components that can contact each other in the operation of the micro device. The inlet to the micro chamber can be subsequently sealed. In contrast, anti-stiction material is conventionally deposited on the surface of the components during the fabrication of the micro devices. The in situ application of anti-stiction material disclosed in the present specification may reduce the device development and testing times.

Furthermore, the chamber encapsulating the micro device can be evacuated, receive the anti-stiction material in vaporized form in the same vacuum environment, and sealed all in the same vacuum environment. No valve is needed in the inlet of the chamber, which also simplifies the design and the fabricating of the encapsulation chamber.

Another potential advantage of the disclosed systems and methods is that the anti-stiction materials can be heated and vaporized in a container separate from the chamber. Thus the micro device and the associated control circuit in the chamber as well as the sealing to the chamber will not be affected by the heating process.

Another potential advantage of the disclosed systems and methods is that anti-stiction materials may be applied to contact areas that are hidden in a micro device. For example, the contact surfaces between a tiltable mirror plate and a landing tip on a substrate can be hidden underneath the mirror plate. The contact surfaces are often formed at the final stage of the device fabrication. The disclosed methods and system may provide a way to isotropically deposit anti-stiction material on the contact surfaces that are hidden by other components of the micro device.

Yet another potential advantage of the systems and method described herein is the prevention of particles being applied to the surfaces of the micromirrors. When particles are prevented from landing on the mirrors, the production yield can be increased.

Although the invention has been particularly shown and described with reference to multiple embodiments, it will be understood by persons skilled in the relevant art that various changes in form and details can be made therein without departing from the spirit and scope of the invention.

### BRIEF DESCRIPTION OF THE DRAWINGS

The following drawings, which are incorporated in and form a part of the specification, illustrate embodiments of the present invention and, together with the description, serve to explain the principles, devices and methods described herein.

FIG. 1 is a flowchart for packaging and applying anti-stiction material to micro devices.

FIG. 2 is a cross sectional view of an exemplified micro device.

FIG. 3 illustrates the transfer of vapor-phase anti-stiction material to an encapsulated micro device.

FIG. 4 is a cross-sectional view of an encapsulated micro device along line A-A in FIG. 3.

FIG. 5 illustrates the transfer of vapor-phase anti-stiction material to several encapsulated micro devices.

FIG. 6 is a cross sectional view of a micro device after it has received the anti-stiction material.

FIG. 7 illustrates a wafer with a plurality of encapsulated micro devices.

FIG. 8 illustrates a system for transferring vapor-phase anti-stiction material to a plurality of encapsulated micro devices.

### DETAILED DESCRIPTION

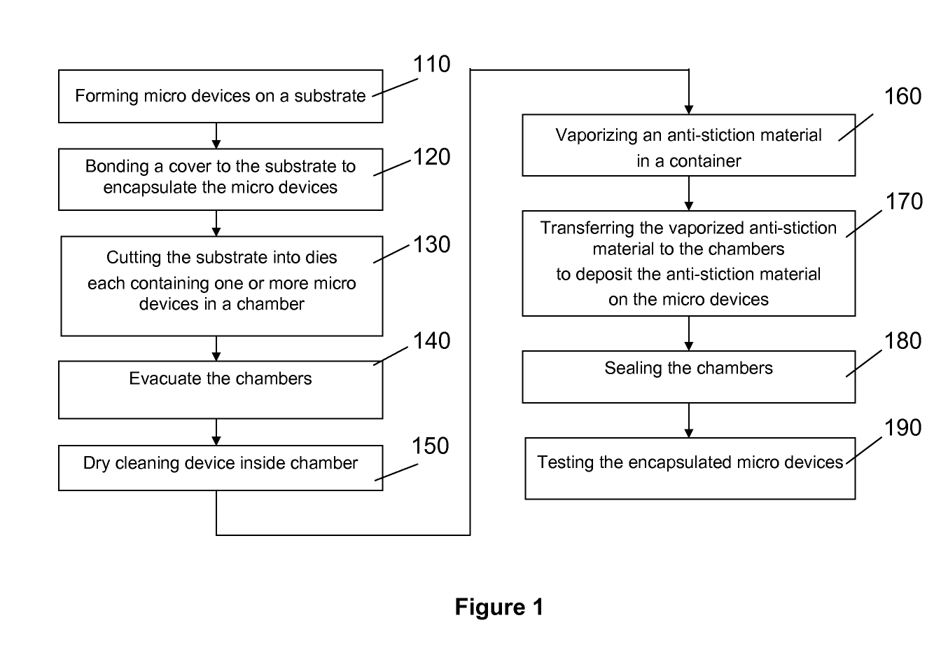

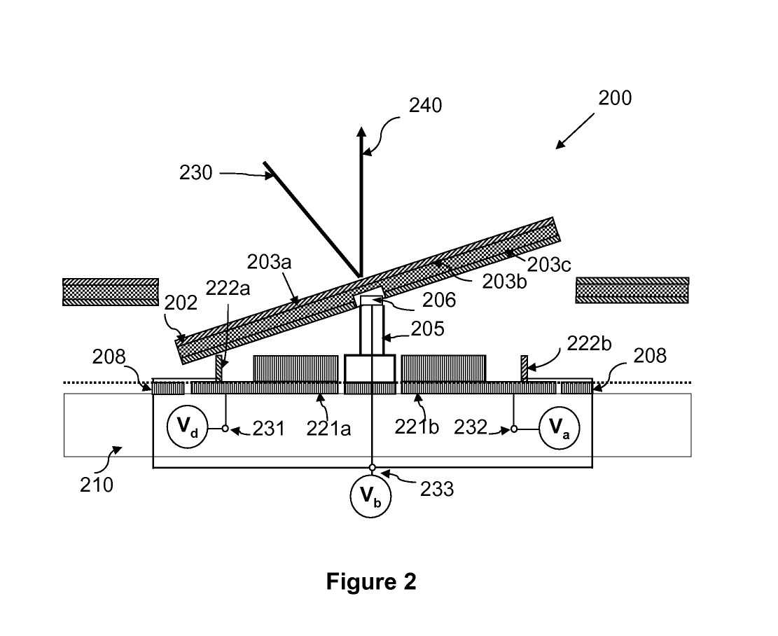

Referring to FIGS. 1 and 2, a micro device 200 is formed on a substrate 210 (step 110). The substrate 210 can be semiconductor wafer including addressing and control electric circuit in a complementary metal-oxide semiconductor (CMOS) layer. The micro device 200 can include a microstructure that can produce a mechanical movement, or can produce electromagnetic signals, acoustic signals, or optical signals in response to an input signal. The micro device can include micromechanical electrical systems (MEMS) such as an array of tiltable micro mirrors, integrated circuits, micro sensors, micro actuators, and light emitting elements. A plurality of micro devices 200 can be formed on the substrate 210.

In one embodiment of a MEMS micro device, the micro device 200 includes a mirror plate 202 that is tiltable around a hinge component 206. The hinge component 206 is supported by a post 205 that is connected to the substrate 210. The mirror plate 202 can include a hinge layer 203c, a spacer layer 203b, and a reflective layer 203a. The reflective layer can reflect an incident light beam in a direction 230 to a direction 240. A pair of electrodes 221a and 221b can be formed on a hinge support frame 208 on the substrate 210. A pair of mechanical stops 222a and 222b can also be formed on the substrate 210 for stopping the tilt movement of the mirror plate 202 and defining precise tilt angles for the mirror plate 202. The hinge layer 203c can be made of an electrically conductive material. The hinge layer 203c and the mechanical stops 222a and 222b can be electrically connected to a common electrode 233. The electrodes 221a and 221b can be separately connected to electrodes 231 and 232. The substrate 210 can include an electric circuit in connection with the electrodes 231-233.

Electric signals can be applied to the electrodes 231-233 to produce electric potential differences between the hinge layer 203c and the electrodes 221a or 221b. Properly designed voltage signals can produce electrostatic torques that can tilt the mirror plate 202 away from an un-tilt direction (which is normally parallel to the upper surface of the substrate 210). The tilting of the mirror plate 202 produces a distortion in a hinge (not shown) connected with the hinge component 205 and an elastic restoring force associated with the distortion. The elastic restoring force pulls the tilted mirror plate 202 back to the un-tilted position. The electrostatic torque can overcome the elastic restoring force to tilt the mirror plate 202 to come into contact with one of the mechanical stops 222a and 222b. The position of the mirror plate 202 when in contact with the mechanical stops 222a or 222b can determine the “on” or the “off” position of the mirror plate and determine the direction 240 of the reflected light. Optionally, the micro devices 200 formed on the substrate 210 are tested by applying external signals to the micro device 20 and measuring mechanical movement of the micro device 200 or output signals produced by the micro device 200.

The micro devices 200 can then be encapsulated (step 120) by bonding an encapsulation cover to the substrate 210. Encapsulation as described herein is not merely covering a device, but permanently enclosing a micro device within one or more layers, such as by adhering the layers together or causing them to be connected in such as way that the encapsulation cannot be pulled away from other layers or parts surrounding the device unless cut or broken. The encapsulation may include an inlet that allows the fluidic communication between inside and outside of the encapsulation in the packaging process of the micro device, as described below. The inlet can be sealed to fully enclose the micro device in the encapsulation. The micro devices 200 and encapsulation cover can then be diced and cut into individual dies 300 each containing one or more micro devices 200 in a chamber 260 (step 130). Details about the encapsulation and dicing of the micro devices are disclosed in the pending U.S. patent application Ser. No. 11/379,932, titled “Micro device encapsulation”, filed Apr. 24, 2006, which is incorporated by reference herein for all purposes.

A common problem for micro devices is stiction between components that contact each other during operation. For example, a mirror plate 202 can tilt to an “on” position, wherein the micro mirror plate directs incident light to a display device, and an “off” position, wherein the micro mirror plate directs incident light away from the display device. The mirror plate 202 can be stopped by mechanical stops 222a and 222b at the “on” or the “off” positions to precisely define tilt angles of the mirror plate 202 at these two positions. The mirror plate 202 stopped at the “on” or the “off” position must be able to overcome stiction between the mirror plate 202 and the mechanical stops 222a and 222b. A delay in the response of the mirror plate 202 can affect the proper operation of the micro mirror 202.

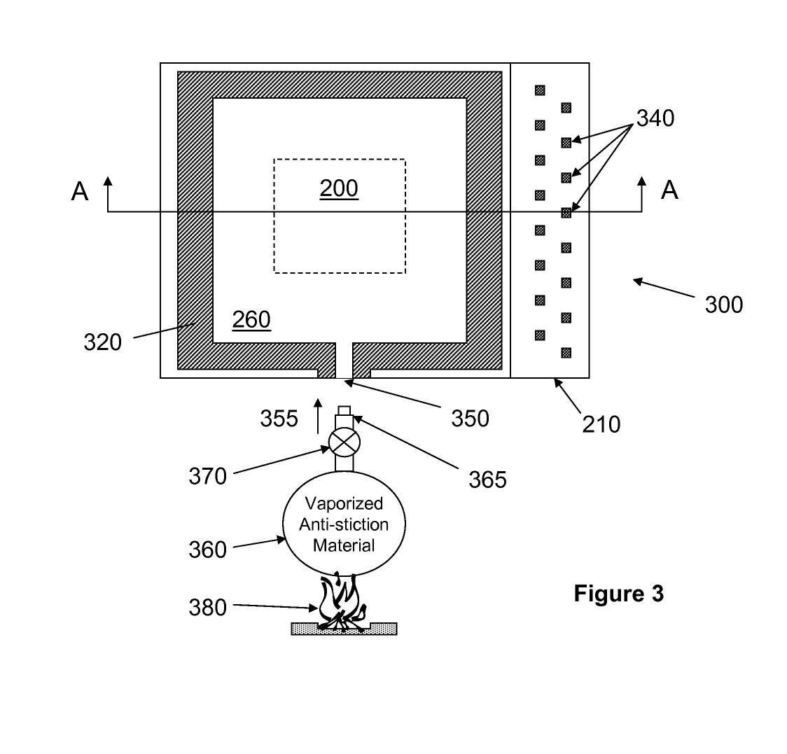

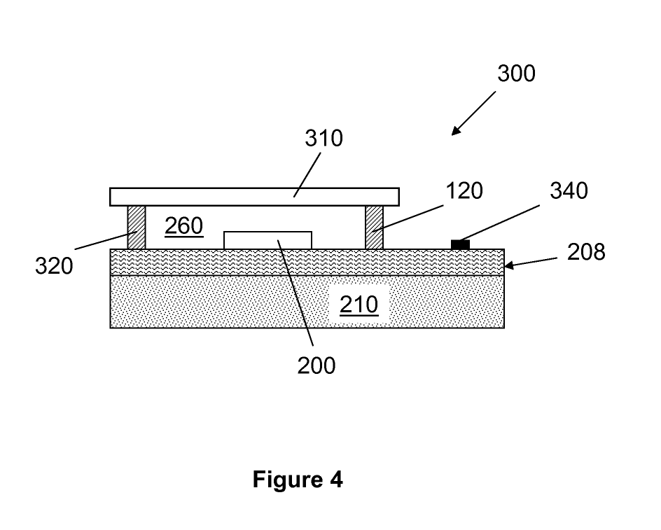

Referring to FIGS. 3 and 4, each die 300 includes one or more micro devices 200 encapsulated in a chamber 260. The chamber 260 is defined by a cover 310 and spacer walls 320. The cover 310 can be transparent to visible, UV, or IR light to allow optical signals to be sent to or received from the micro device 200 through the cover 310. One or more electric contacts 340 can be formed on the substrate 210 outside of the chamber 260. The electric contacts 340 are provided for sending electric signals to the micro device 200 or receiving electric signals from the micro device 200. An inlet 350 is in fluid communication with the chamber 260 and in some embodiments, is directly adjacent to the chamber. Optionally, the die 300 is placed in a vacuum environment to exhaust the air or gas in the chamber 260 (step 140). The devices can be cleaned, such as by a dry clean process after the chamber 260 has been evacuated (step 150).

The inlet 350 to the chamber 260 is configured to be connected with the outlet 365 of a container 360. The outlet 365 of the container 360 can be opened or closed by a valve 370. The container 360 contains an anti-stiction material. Examples of the anti-stiction material compatible with the disclosed system and methods can include tridecafluoro-1,1,2,2,-tetrahydrooctyltrichlorosilane (FOTS) or heptadecafluoro-1,1,2,2,-tetrahydrooctyltrichlorosilane (FDTS).

If the anti-stiction material is in a non-vapor form, the anti-stiction material is heated by a heat source 380 while the valve 370 is in a closed position. The vaporized anti-stiction material is in the container 360 (step 160). Before heating, the anti-stiction material can be in a solid state, a liquid state, or a polymer melt. The vaporization process can thus include evaporation or sublimation of the anti-stiction material. The outlet 365 of the container 360 is then moved in the direction 355 to be coupled with the inlet 350 of the chamber 260 to allow fluidic communication between the chamber 260 and the container 360.

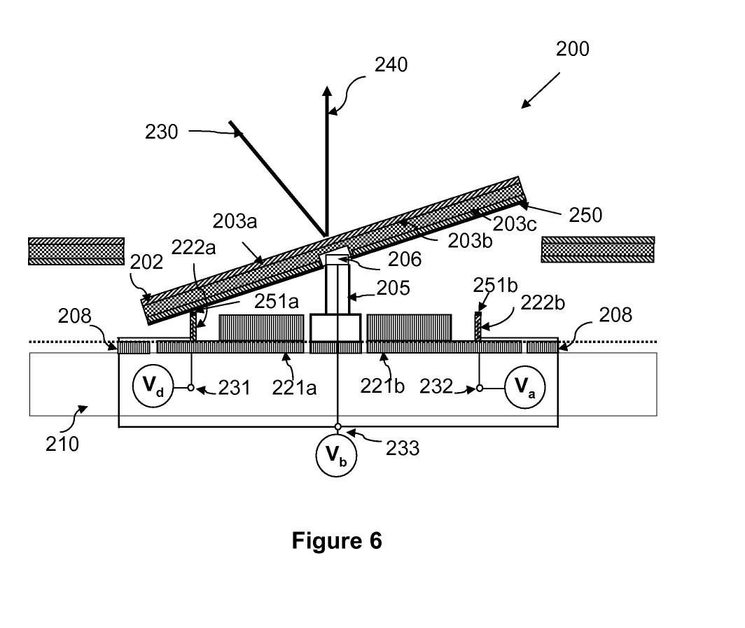

The vaporized anti-stiction material is transferred from the container 360 to the chamber 260 (step 170). For example, the vaporized anti-stiction material can diffuse from the container 360 to the chamber 260, which can be driven by the higher vapor concentration in the container 260 compared to the low-pressure degassed environment in the chamber 260. The vaporized anti-stiction material cools and deposits on the surface of the micro device 200. For example, as shown in FIG. 6, anti-stiction material 250 can be deposited on the lower surface of the hinge layer 203c. Anti-stiction material 251a and 251b can be deposited respectively on the upper surfaces of the mechanical stops 222a and 222b. The anti-stiction material 250, 251a and 251b coated on the contact surfaces of the mirror plate 202 and the mechanical stops 222a and 222b can help the mirror plate 202 to overcome the stiction at the contact surface and ensure timely tilt response by the mirror plate 202. The anti-stiction material may also be deposited on the surface of the reflective layer 203a. In some embodiments, the deposition can be controlled such that the layer thickness of the anti-stiction material is kept much shorter than the wavelength of light (visible, UV, or IR light). For example, the layer thickness of the anti-stiction material deposited on the reflective layer 203a can be controlled at 1-50 nanometers, or in one or a few monolayers. The layer thickness can be controlled for example by the time and temperature at which the container 360 is heated and the valve 370 is opened during the vapor transfer.

An advantage of the disclosed process is that the vaporization of the anti-stiction material does not require the heating of the micro devices. The micro device, the electric circuit in the (CMOS) substrate, and the encapsulation sealing of chamber 260 thus are not be affected by the heating process.

Another advantage of the disclosed process is that anti-stiction material can be applied to contact areas that are hidden in a micro device after the micro device is fully formed. The disclosed methods of application of the anti-stiction material do not require additional steps in the fabrication of the micro device. For example, the lower surface of the hinge layer 203c and the upper surfaces of the mechanical stops 222a and 222b are hidden under the mirror plate 202 and are not readily accessible if the anti-stiction material were applied from above the mirror plate 202. It can thus be difficult to apply anti-stiction material from above the mirror plate 202. Using the disclosed methods, vaporized anti-stiction material can be isotropically deposited on the contact surfaces that are hidden by other components of the micro device.

The inlet 350 is subsequently sealed (step 180). In some embodiments, the inlet 350 is sealed with an epoxy seal. The micro device 200 having the deposited anti-stiction material can be further tested in the encapsulated environment in the chamber 260 by applying or receiving electric signals to the electric contacts 340 or using optical communications through a transparent cover 310 (step 190). An advantage of the disclosed system and methods is that the chamber 260 can stay in a same vacuum environment for the application of the anti-stiction material and the subsequent sealing of the inlet 350.

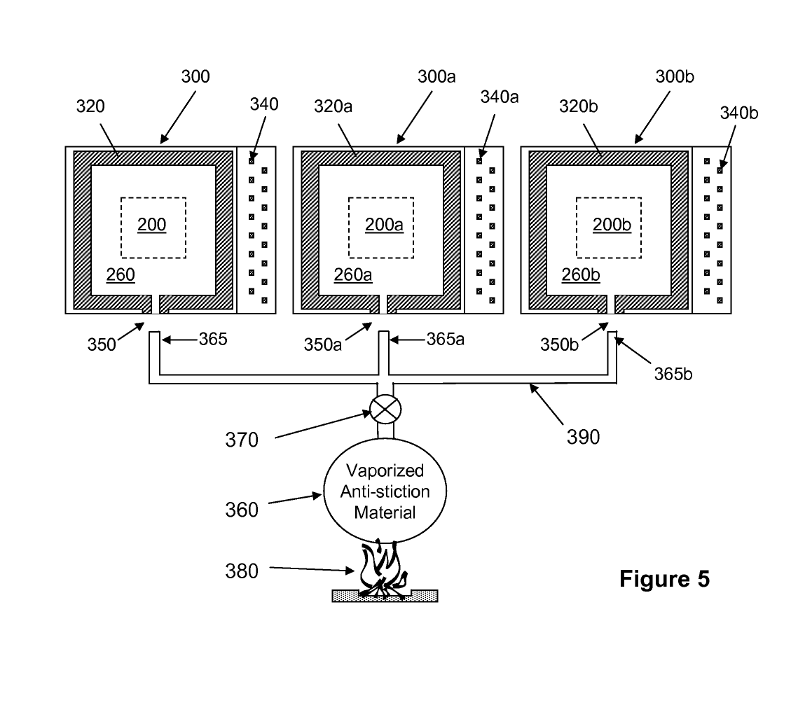

In some embodiments, as shown in FIG. 5, the container 360 can be coupled to a plurality of chambers 260, 260a and 260b on a multiple of dies 300, 300a and 300b. Each die 300, 300a and 300b can include electric contracts 340, 340a and 340b for electrical communications from outside of the chambers 260, 260a and 260b. The container 360 includes a conduit 390 that can be multiplexed to a plurality of outlets 365, 365a, and 365b. The outlets 365, 365a, and 365b can be connected to the inlets 350, 350a and 350b in the chambers 260, 260a and 260b to allow fluidic communication between the chamber 260, 260a, or 260b and the container 360. The vaporized anti-stiction material produced in the container 360 can thus be simultaneously transferred to a plurality of chambers 260, 260a and 260b.

In some embodiments, the transfer of the vaporized anti-stiction material is conducted on a single substrate that includes a plurality of chambers each containing one or more micro devices. The plurality of outlets 365, 365a, and 365b can be aligned and engaged with the inlets of the plurality of chambers on the common substrate. The vaporized anti-stiction material can be transferred to the chambers and the respectively encapsulated micro devices. The chambers can then be sealed and are cut into individual dies each containing one or more encapsulated micro devices. The processes described herein allow for applying the anti-stiction material at either the die level or the wafer level. It is understood that the disclosed systems and methods are compatible with a variety of anti-stiction materials. The disclosed system and methods are also compatible with different configurations of the device-encapsulation chambers and containers for holding the vaporized anti-stiction materials. The micro device can generally include micromechanical electrical systems (MEMS) such as tiltable micro mirrors, integrated circuits, micro sensors, micro actuators, and light emitting elements.

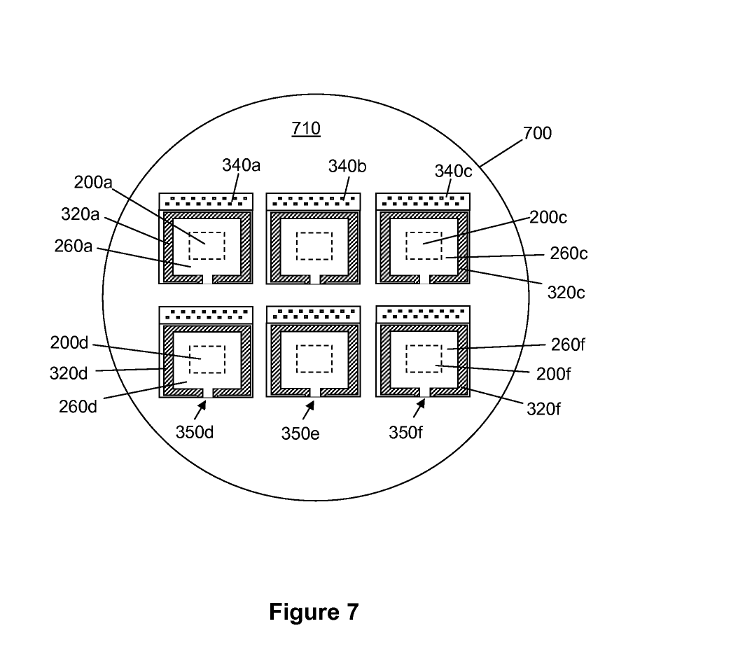

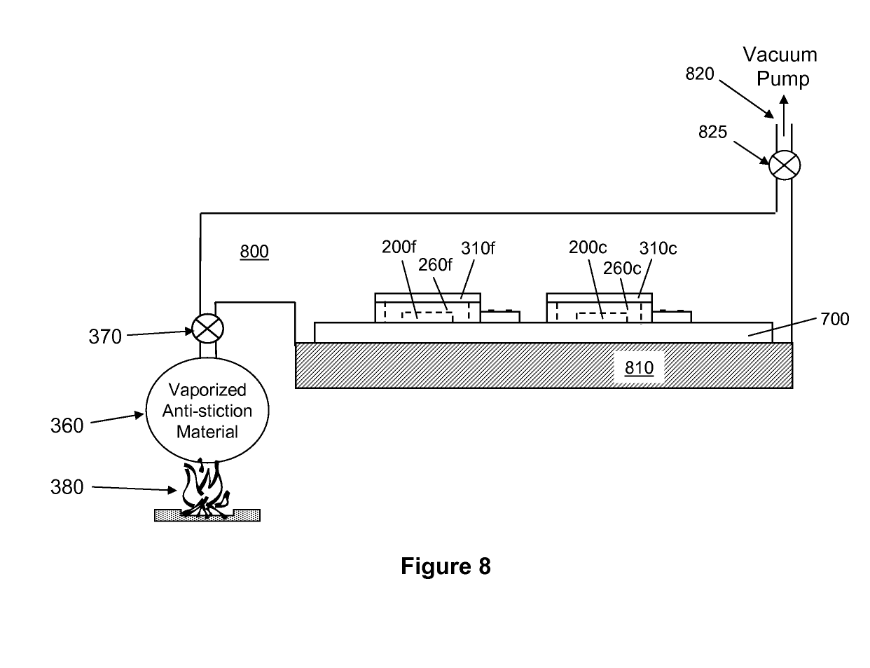

In some embodiments, referring to FIGS. 7 and 8, a plurality of chambers 260a-260f are formed on a wafer 700. Each chamber 260a-260f includes spacer walls 320a-320f and a cover 310a-310f that encapsulates a micro device 200a-200f. Each chamber 260a-260f can also include an inlet 350a-350f. Each micro device 200a-200f is connected with electric contracts 340a-340f that provide electrical communications from outside of the chambers 260a-260f. The chambers 260a-260f can be formed by bonding a cover having a plurality of spacer walls to the wafer 700. The cover can then be selectively cut to expose areas 710 and the electric contracts 340a-340f on the wafer 700.

The wafer 700 including the chambers 260a-260f and the respective encapsulated micro devices 200a-200f can be placed in a chamber 800 for the transfer of anti-stiction material to the micro devices 200a-200f. In some embodiments, the wafer is placed on a temperature controlled substrate 810. An outlet 820 in the chamber 800 can be connected with a vacuum pump that evacuates air or fluid from the chamber 800 when a valve 825 is opened. A vacuum state can be maintained in the chamber 800 when the valve 825 is closed. Vaporized anti-stiction material is produced in the container 360. The vaporized anti-stiction material can be transferred from the container 360 to the chamber 800 when the valve 370 is opened. The vaporized anti-stiction material is subsequently transferred into individual chambers 260a-260f through inlets 350a-350f and deposited on the surfaces of the micro devices 200a-200f. After the transfer of the anti-stiction material, the inlets 350a-350f can be sealed in vacuum by epoxy that can be applied to the inlets 350a-350f, for example, by a dispenser.

The methods and systems described herein can provide advantages in terms of manufacturing the MEMS devices. During manufacturing, the risk of particles, such as dust or other debris from the air, of landing on the MEMS device is typically present. Particles of about 1 micron or greater on the MEMS device surface, particularly on the surface of a micromirror, can reduce the functionality of the device, even to the point that the device is not useful. Reducing the likelihood of particles landing on the MEMS device surfaces can create cleaner devices. In turn, the manufacturing yield may be increased using the methods and systems described herein.

What is claimed is:

1. A method for applying anti-stiction material to a micro device, comprising:
encapsulating a micro device in a chamber;
vaporizing anti-stiction material in a container to form vaporized anti-stiction material;
transferring the vaporized anti-stiction material from the container into the chamber through an inlet in fluid communication with the chamber; and
depositing the vaporized anti-stiction material on a surface of the micro device.

2. The method of claim 1, further comprising evacuating the chamber before the step of transferring.

3. The method of claim 1, wherein the step of transferring comprises diffusing the vaporized anti-stiction material into the chamber.

4. The method of claim 1, wherein the step of transferring comprises connecting an outlet of the container with an inlet of the chamber to permit fluidic communication between the container and the chamber.

5. The method of claim 4, wherein the step of transferring comprises opening a valve at the outlet of the container.

6. The method of claim 4, further comprising sealing the inlet of chamber after the step of transferring.

7. The method of claim 1, wherein the step of vaporizing comprises heating the anti-stiction material.

8. The method of claim 7, wherein the step of vaporizing comprises evaporating the anti-stiction material.

9. The method of claim 7, wherein the step of vaporizing comprises subliming the anti-stiction material.

10. The method of claim 1, wherein the micro device comprises a first component and a second moveable component configured to contact the first component.

11. The method of claim 10, further comprising depositing the vaporized anti-stiction material on a surface of the first component or a surface of the second moveable component to prevent stiction between the first component and the second moveable component.

12. The method of claim 10, wherein the second moveable component is a micro mirror plate configured to tilt.

13. The method of claim 1, wherein the chamber comprises a window transparent to at least one of visible, UV, or IR light.

14. The method of claim 1, wherein the anti-stiction material comprises tridecafluoro-1,1,2,2,-tetrahydrooctyltrichlorosilane (FOTS) or heptadecafluoro-1,1,2,2,-tetrahydrooctyltrichlorosilane (FDTS).

15. A micromechanical system, comprising:
a chamber comprising an inlet to permit the transfer of a vaporized anti-stiction material into the chamber;
a micro device encapsulated in the chamber, wherein the micro device comprises a first component and a second moveable component configured to contact the first component; and
anti-stiction material coated on a surface of the first component or the second moveable component to prevent stiction between the first component and the second moveable component.

16. The micromechanical system of claim 15, wherein the anti-stiction material comprises tridecafluoro-1,1,2,2,-tetrahydrooctyltrichlorosilane (FOTS) or heptadecafluoro-1,1,2,2,-tetrahydrooctyltrichlorosilane (FDTS).

17. The micromechanical system of claim 15, wherein the anti-stiction material coated on surface of the first component or the second moveable component is thicker than 0.3 nanometer.

18. The micromechanical system of claim 17, wherein the anti-stiction material coated on the surface of the first component or the second moveable component is thicker than 1.0 nanometer.

19. The micromechanical system of claim 15, wherein the chamber is at least partially evacuated.

20. The micromechanical system of claim 19, wherein the inlet of chamber is sealed.

21. The micromechanical system of claim 15, wherein the second moveable component is configured to move to contact the first component in response to an external signal.

22. The micromechanical system of claim 15, wherein the second moveable component is a micro mirror plate configured to tilt in response to an external electric signal.

23. The micromechanical system of claim 15, wherein the chamber comprises a window transparent to at least one of visible, UV, or IR light.

24. The micromechanical system of claim 23, wherein at least one surface of the window is coated with a layer of anti-reflective material.

25. The micromechanical system of claim 15, further comprising a substrate on which the micro device is mounted, wherein the substrate comprises an electric circuit configured to transmit electric signals to control the micro device.
